(19) United States
(12) Patent Application Publication
(10) Pub. No.: US 2007/0257581 A1
(43) Pub. Date: Nov. 8, 2007

(54) Piezoelectric actuator and method of producing the same

(75) Inventor: Kaneo Buma, Oobu-shi (JP)

Correspondence Address: NIXON & VANDERHYE, PC, 901 NORTH GLEBE ROAD, 11TH FLOOR, ARLINGTON, VA, 22203, US

(73) Assignee: Denso Corporation, Kariya-city (JP)

(21) Appl. No.: 11/730,809

(22) Filed: Apr. 4, 2007

(30) Foreign Application Priority Data
Apr. 7, 2006 (JP) 2006-106762

(51) Int. Cl. H01L 41/083

(52) U.S. Cl. 310/348; 310/328

(57) ABSTRACT

A piezoelectric actuator includes a stacked piezoelectric device received in a cylindrical case having an extendable and contractible portion formed at least at an axial part thereof, and a housing provided with a pair of external electrodes for power supply and connected to an open end of the cylindrical case. Between the piezoelectric device and the cylindrical case, a molding resin having an electric insulation property is provided on an outer circumferential surface of the piezoelectric device, and a sleeve having an electric insulation property is provided on the molding resin. The sleeve is formed by a plurality of circumferentially separated sleeve segments assembled together into a substantially cylindrical shape.

### CROSS REFERENCE TO RELATED APPLICATION

The present application is based on and claims priority from Japanese Patent Application 2006-106762, filed April 7, 2006, the contents of which are incorporated herein by reference.

### BACKGROUND OF THE INVENTION

1. Field of the Invention

The present invention relates to a piezoelectric actuator having a piezoelectric device received in a case and a method of producing the piezoelectric actuator.

2. Description of the Related Art

Piezoelectric actuators for used in a fuel injector of an internal combustion engine of an automobile or the like are known heretofore, which comprise a piezoelectric device drivable upon application of an electric voltage is received in a tightly-sealed fashion within a case having an extendable and contractible portion in the form of a metal bellows. One example of such known piezoelectric actuators is disclosed in Japanese Patent Laid-open Publication (JP-A) No. 2002-256999, which corresponds to U.S. Pat. No. 6,563,687. The disclosed piezoelectric actuator includes an insulating member having an electric insulation property (hereinafter referred to, for brevity, as “insulation property”) disposed between the piezoelectric device and the case so as to provide insulation therebetween.

To ensure the desired insulating property of the electric actuator, a cylindrical sleeve formed from an insulating resin is provided around an outer peripheral surface of the piezoelectric device via a molding resin having an insulation property. In the manufacture of such piezoelectric actuator, the molding resin is applied to the outer peripheral surface of the piezoelectric device and, thereafter, the piezoelectric device is inserted in the cylindrical sleeve. In this instance, however, since the molding resin applied to the outer peripheral surface of the piezoelectric device is brought into contact with the sleeve, it is difficult for the molding resin to maintain the homogeneity thereof. For instance, if the amount of molding resin applied to the piezoelectric device is excessively large, the molding resin will be squeezed out from the sleeve, requiring a separate work or process for removing the squeeze-out of the molding resin.

Another conventional piezoelectric actuator includes an insulation resin filled as a filling material between a piezoelectric device and a case. In the manufacture of such conventional piezoelectric actuator, the insulating resin is filled by injection between the piezoelectric device and the case. However, due to an extremely narrow space formed between the piezoelectric device and the case, the filler injecting operation is very difficult to achieve and hence lowers the productivity of the piezoelectric actuator.

With the foregoing difficulties in view, an object of the present invention is to provide a piezoelectric actuator, which has an excellent electric insulation property and is capable of improving the productivity, and a method of producing such piezoelectric actuator.

### SUMMARY OF THE INVENTION

According to a first aspect of the present invention, there is provided a piezoelectric actuator comprising: a case having a bottomed cylindrical shape including an extendable and contractible portion formed at least at a part of the cylindrical case in an axial direction thereof; a stacked piezoelectric device received in the cylindrical case; a housing provided with a pair of external electrodes for power supply and connected to an open end of the cylindrical case; a molding resin having an electric insulation property and provided on an outer circumferential surface of the piezoelectric device between the piezoelectric device and the cylindrical case; and a sleeve having an electric insulation property and provided on the molding resin, the sleeve being formed by a plurality of circumferentially separated sleeve segments assembled together into a substantially cylindrical shape.

In the piezoelectric actuator of the present invention, the stacked piezoelectric device is received or housed in the case having a bottomed cylindrical shape. Between the piezoelectric device and the cylindrical case, the sleeve is provided on the outer circumferential surface of the piezoelectric device with the molding resin disposed therebetween. The sleeve is formed by the sleeve segments, which are separated in a circumferential direction and assembled together into a substantially cylindrical shape.

Unlike the conventional sleeve having a one-piece unitary structure adapted to be fitted around the piezoelectric device by insertion of the piezoelectric device into the sleeve, the sleeve of the present invention has a split structure composed of a plurality of circumferentially separated sleeve segments that can be mated or assembled together into a substantially cylindrical shape provided on and around the outer circumferential surface of the piezoelectric device. In the manufacture of the piezoelectric actuator, positioning of the sleeve segments in a circumferential direction can be easily achieved so that the sleeve can be formed with high accuracy.

Furthermore, since the sleeve is formed by placing the sleeve segments on and around the outer circumferential surface of the piezoelectric device while confirming or monitoring the application quantity and condition of the molding resin interposed between the piezoelectric device and the sleeve, it is possible to prevent homogeneity degradation and squeeze-out of the molding resin which would otherwise occur when the sleeve has a conventional one-piece unitary structure. Thus, the film thickness of the molding resin can be readily controlled, which will ensure a sufficient degree of uniformity in film thickness of the molding resin.

Additionally, by virtue of the sleeve accurately provided on the outer circumferential surface of the piezoelectric device via the molding resin having a uniform film thickness, sufficient insulation can be provided between the piezoelectric device and the case. Furthermore, the piezoelectric actuator of the invention has very high quality particularly in terms of the durability and reliability.

Moreover, since the film thickness of the molding resin can be easily controlled as previously described, it is possible to perform application of the molding resin with a minimum necessary quantity. As a consequence, excess application of the molding resin can be avoided and a separate work or operation for removing an excess amount of molding resin is no longer necessary. Thus, the piezoelectric actuator is able to improve the productivity.

As thus far described, the piezoelectric actuator according to the invention has an excellent electric insulation property, which leads to an improvement in the quality in terms of the durability and reliability, and is capable of improving the productivity of the piezoelectric actuator.

Preferably, the sleeve has a large-diameter portion formed on an outer circumferential surface thereof for the purpose of alignment, the large-diameter portion being in contact with an inner circumferential surface of the cylindrical case. With the large-diameter portion thus provided, the distance between the piezoelectric device and the case can be maintained uniformly and the axis of the piezoelectric device is fixed in position. As a result, the piezoelectric device is held in alignment with the case without involving eccentricity therebetween. This will increase the durability of the piezoelectric actuator.

It is preferable that sleeve has a communicating hole formed at mating portions of each adjacent two of the plurality of sleeve segments, and the molding resin disposed inside the sleeve is exposed to the view through the communicating hole. By thus providing the communicating hole, it is readily possible to confirm, through visual observation through the communicating hole, whether the molding resin has been applied (or filled) uniformly and sufficiently between the piezoelectric device and the sleeve. With this visual observation, the film thickness of the molding resin can be controlled easily and accurately.

Preferably, each of the sleeve segments has an engagement portion disposed on an end surface of a respective mating portion, and the engagement portion of each sleeve segment is engaged with the engagement portion of the adjacent sleeve segment so that the sleeve segments are assembled together into the cylindrical sleeve. This arrangement facilitates easy positioning of the sleeve segments in the circumferential direction of the sleeve, which will ensure reliable joining of the sleeve segments. The sleeve formed by such sleeve segments is assembled with a high degree of accuracy and has a sufficient strength.

Preferably the piezoelectric actuator is incorporated in a fuel injector of an internal combustion engine. The fuel injector is used under severe conditions involving high temperatures and humidity. However, by using the piezoelectric actuator of the invention, the fuel injector is improved in its durability and reliability, which will increase operation performance of the fuel injector.

According to a second aspect of the present invention, there is provided a method of producing a piezoelectric actuator comprised of a case having a bottomed cylindrical shape including an extendable and contractible portion formed at least at a part of the cylindrical case in an axial direction thereof, a stacked piezoelectric device received in the cylindrical case, and a housing provided with a pair of external electrodes for power supply and connected to an open end of the cylindrical case, the method comprising the steps of: applying a molding resin having an electric insulation property to at least one of an outer circumferential surface of the piezoelectric device and inner circumferential surfaces of a plurality of circumferentially separated sleeve segments having an electric insulation property; placing the sleeve segments on the outer circumferential surface of the piezoelectric device in a circumferentially mated condition with the molding resin interposed between the piezoelectric device and the sleeve segments to thereby assemble the sleeve segments together into a substantially cylindrical sleeve; curing the molding resin; placing the piezoelectric device into the cylindrical case; and placing the housing in such a manner as to close an open end of the cylindrical case and joining the housing and the case together.

As will be understood from the foregoing, the piezoelectric actuator production method of the present invention generally comprises a resin application step, a sleeve assembly step, a resin curing step, a piezoelectric device placement step, and a housing and case joining step that are performed in the named order. In the sleeve assembly step, the plural sleeve segments are placed on the outer circumferential surface of the piezoelectric device in a circumferentially mated condition with the molding resin interposed between the piezoelectric device and the sleeve segments to thereby assemble the sleeve segments together into a substantially cylindrical sleeve.

In the sleeve assembly step, instead of inserting the piezoelectric device into a cylindrical sleeve of one-piece unitary structure to thereby provide the sleeve on and around the outer circumferential surface of the piezoelectric device as done in the conventional piezoelectric actuator production method, a split sleeve composed of a plurality of sleeve segments separated in advance in a circumferential direction of the sleeve is used and the sleeve segments are placed on and around the outer circumference surface of the piezoelectric device and mated or assembled together in the circumferential direction to thereby form the sleeve of a cylindrical shape. Positioning of the sleeve segments in the circumferential direction is easy to achieve so that the sleeve can be formed with high accuracy.

Furthermore, in the sleeve assembly step, the sleeve is formed by placing the sleeve segments on and around the outer circumferential surface of the piezoelectric device while confirming or monitoring the application quantity and condition of the molding resin interposed between the piezoelectric device and the sleeve. It is therefore possible to prevent homogeneity degradation and squeeze-out of the molding resin, which would otherwise occur when the sleeve has a conventional one-piece unitary structure. Thus, the film thickness of the molding resin can be controlled easily and the uniformity in thickness of the molding resin can be maintained sufficiently.

Additionally, by virtue of the sleeve which is accurately provided on the outer circumferential surface of the piezoelectric device with the molding resin having a uniform film thickness disposed therebetween, it is possible to provide sufficient insulation between the piezoelectric device and the case. As a result, the piezoelectric actuator produced in accordance with the method of the present invention has very high quality, which is particularly excellent in terms of the durability and reliability.

Furthermore, according to the method of the present invention, the film thickness of the molding resin can be easily controlled as previously described and, accordingly, application quantity of the molding resin can be limited to a minimum necessary quantity. As a consequence, excess application of the molding resin can be avoided and a separate work or operation for removing an excess amount of molding resin is no longer necessary. Thus, the productivity of the piezoelectric actuator is improved.

As thus far described, the piezoelectric actuator production method of the present invention is able to improve the productivity of the piezoelectric actuator and can provide a piezoelectric actuator which is excellent in electric insulation property, leading to an improvement in the quality in terms of the durability and reliability.

The resin application step may be carried out by applying the molding resin to the outer circumferential surface of the piezoelectric device. In this instance, the sleeve assembly step is carried out by placing the sleeve segments on the outer peripheral surface of the piezoelectric device to which the molding resin has been applied. With this arrangement of the processing steps, the sleeve segments can be placed to form the sleeve while confirming or monitoring the application quantity and condition of the molding resin. It is therefore possible to make the film thickness of the molding resin uniform, leading to formation of a sleeve with increased accuracy.

Alternatively, the resin application step may be carried out by applying the molding resin to the respective inner circumferential surfaces of the sleeve segments. In this instance, the sleeve assembly step is carried out by placing the sleeve segments on the outer peripheral surface of the piezoelectric device with the molding resin being applied to the inner circumferential surfaces of the sleeve segments. In this case, the sleeve segments can be placed to form the sleeve while confirming or monitoring the application quantity and condition of the molding resin. Thus, the film thickness of the molding resin can be made uniform, which will leads to formation of a sleeve with increased accuracy.

As a further alternative, the resin application step may be carried out by applying the molding resin to side surface electrodes which are connected to the respective external electrodes and provided on a pair of electrode bonding surfaces formed on the outer circumferential surface of the piezoelectric device, and also applying the molding resin by stamp-bonding to that part of the inner circumferential surfaces of the sleeve segments which will be finally placed on that part of the outer circumferential surface of the piezoelectric device which is free from the molding resin. In this instance, the sleeve assembly step is carried out by placing the sleeve segments on the outer circumferential surfaces of the piezoelectric device in such a manner that the molding resin applied to the sleeve segments is in match with the molding resin-free part of the outer peripheral surface of the piezoelectric device. In the same way as discussed above, the sleeve segments can be placed to form the sleeve while confirming or monitoring the application quantity and condition of the molding resin. Thus, the film thickness of the molding resin can be made uniform, which will leads to formation of a sleeve with increased accuracy. Furthermore, by using the stamp bonding, it is readily possible to apply a necessary amount of molding resin only to a desired part of the sleeve segments. Accordingly, excess application of the molding resin can be avoided.

Preferably, the sleeve assembly step further comprises providing a large diameter portion formed on an outer circumferential surface of the sleeve for the purpose of alignment. In this case, the axis of the piezoelectric device can be adjusted in position relative to the case by means of the large-diameter portion so that the piezoelectric device and the case are aligned with each other without involving eccentricity therebetween. With this alignment, the piezoelectric actuator is improved in terms of vibration resistance.

In the piezoelectric device placement step, the piezoelectric device is preferably placed in the cylindrical case such that the large-diameter portion of the sleeve is in contact with an inner circumferential surface of the case. In this instance, since the large-diameter portion operates to keep constant spacing between the piezoelectric device and the case and fix the axis of the piezoelectric device in position relative to the case. This will ensure that the piezoelectric device is completely free from eccentricity relative to the case and the vibration resistance of the piezoelectric actuator increases further.

Preferably, the sleeve assembly step is achieved such that positioning engagement portions provided on end surfaces of respective mating portions of two adjacent ones of the sleeve segments are engaged together to assemble the sleeve segments into the cylindrical sleeve. In this case, positioning of the sleeve segments in the circumferential direction can be achieved more easily and the sleeve segments can be joined with increased reliability. Regardless of its split structure composed of a plurality of sleeve segments, the sleeve is highly accurate in construction and has a high mechanical strength.

The sleeve assembly step may be carried out in such a manner that a communicating hole is formed at mating portions of each adjacent two of the sleeve segments when the sleeve segments are assembled together into the cylindrical sleeve, and the molding resin disposed inside the sleeve is exposed to the view through the communicating hole. In this case, it is readily possible to perform a visual observation through the communicating hole so as to confirm whether the molding resin has been applied (or filled) uniformly and sufficiently between the piezoelectric device and the sleeve. With this visual observation, the film thickness of the molding resin can be controlled easily and accurately. If the visual observation uncovers insufficient application of the molding resin, a necessary amount of molding resin will be replenished from the communicating hole. Alternatively, if an excessively large amount of molding resin has been applied, excess molding resin is squeezed out from the communicating hole. The squeeze-out of the molding resin can be removed without difficulty.

Preferably, the sleeve segments are formed from polyphenylene sulfide (PPS), polyethylene terephthalate (PET), or nylon 66 (NY66). By using one of these materials, the sleeve can be formed with high accuracy and is able to provide sufficient electric insulation between the piezoelectric device and the case. The sleeve segments may be formed from other materials where appropriate.

Furthermore, it is preferable that the molding resin is a silicone resin, epoxy resin, polyimide resin, or polyurethane resin. By using one of these materials, it is possible for the molding resin to insure accurate and reliable formation of a sleeve on the outer circumferential surface of the piezoelectric device and also provide a sufficient electric insulation between the piezoelectric device and the case. Other materials may be used for the molding resin where appropriate.

### BRIEF DESCRIPTION OF THE DRAWINGS

FIG. 1 is a front elevational view with parts shown in cross section of a piezoelectric actuator according to a first embodiment of the present invention;

FIG. 2 is a cross-sectional view taken along line II-II of FIG. 1;

FIG. 3 is a perspective view of a piezoelectric device of the piezoelectric actuator;

FIG. 4 is a perspective view showing the manner in which sheet pieces are stacked to form a ceramic stacked body of the piezoelectric actuator;

FIG. 5 is a schematic perspective view of the ceramic stacked body;

FIG. 6 is an explanatory front elevational view showing a piezoelectric device and a housing of the piezoelectric actuator as they are assembled together;

FIG. 7A is an explanatory view showing a resin application step of a piezoelectric actuator production method according to the first embodiment of the present invention;

FIG. 7B is an explanatory cross-sectional view taken along line VII-VII of FIG. 7A;

FIG. 8A is an explanatory view showing a sleeve assembly step of the piezoelectric actuator production method according to the first embodiment of the present invention;

FIG. 8B is an explanatory cross-sectional view taken along line VIII-VIII of FIG. 8A;

FIG. 9A is an explanatory view showing a piezoelectric device and a sleeve as assembled together according to the first embodiment of the production method of the present invention;

FIG. 9B is an explanatory cross-sectional view taken along line IX-IX of FIG. 9A;

FIG. 10 is an explanatory view showing a piezoelectric device placement step of the piezoelectric actuator production method according to the first embodiment of the present invention;

FIG. 11A is an explanatory view showing a resin application step of the piezoelectric actuator production method according to a second embodiment of the present invention;

FIG. 11B is an explanatory cross-sectional view taken along line XI-XI of FIG. 11A;

FIG. 12A is an explanatory view showing a sleeve assembly step of the piezoelectric actuator production method according to the second embodiment of the present invention;

FIG. 12B is an explanatory cross-sectional view taken along line XII-XII of FIG. 12A;

FIG. 13A is an explanatory view showing a first part of the resin application step of the piezoelectric actuator production method according to a third embodiment of the present invention;

FIG. 13B is an explanatory cross-sectional view taken along line XIII-XIII of FIG. 13A;

FIG. 14A is an explanatory view showing a second part of the resin application step of the piezoelectric actuator production method according to the third embodiment of the present invention;

FIG. 14B is an explanatory cross-sectional view taken along line XIV-XIV of FIG. 14A;

FIG. 15A is an explanatory view showing a sleeve assembly step of the piezoelectric actuator production method according to the third embodiment of the present invention;

FIG. 15B is an explanatory cross-sectional view taken along line XV-XV of FIG. 15A;

FIG. 16 is a front elevational view with parts shown in cross section of a piezoelectric actuator according to a fourth embodiment of the present invention; and

FIG. 17 is an explanatory view showing a construction of an injector according to a fifth embodiment of the present invention.

### DETAILED DESCRIPTION OF THE PREFERRED EMBODIMENTS

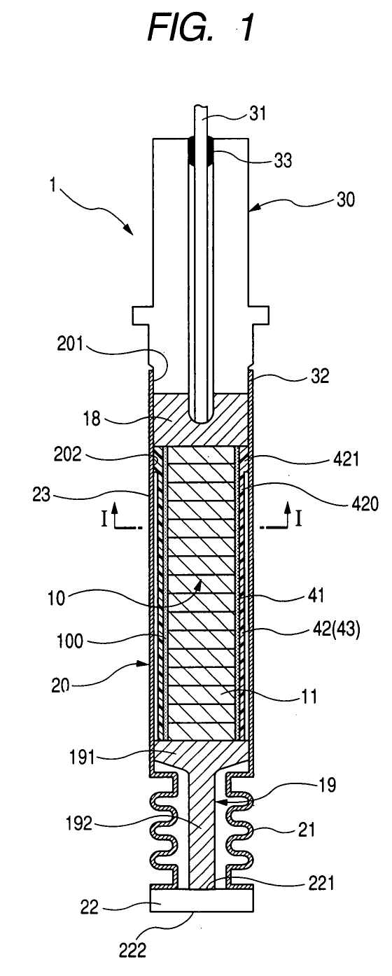

A piezoelectric actuator and a method of producing the same will be described below with reference to a first embodiment shown in FIGS. 1 through 10. As shown in FIG. 1, the piezoelectric actuator 1 according to the first embodiment of the present invention generally comprises a case 20 having a bottomed cylindrical shape including an extendable and contractible portion 21 formed at least at a part of the cylindrical case 20 in an axial direction thereof, a stacked actuator device 10 received or housed in the cylindrical case 20, and a housing 30 provided with a pair of external electrodes 31 for power supply to the piezoelectric actuator 1 and connected to an open end 201 of the cylindrical case 20.

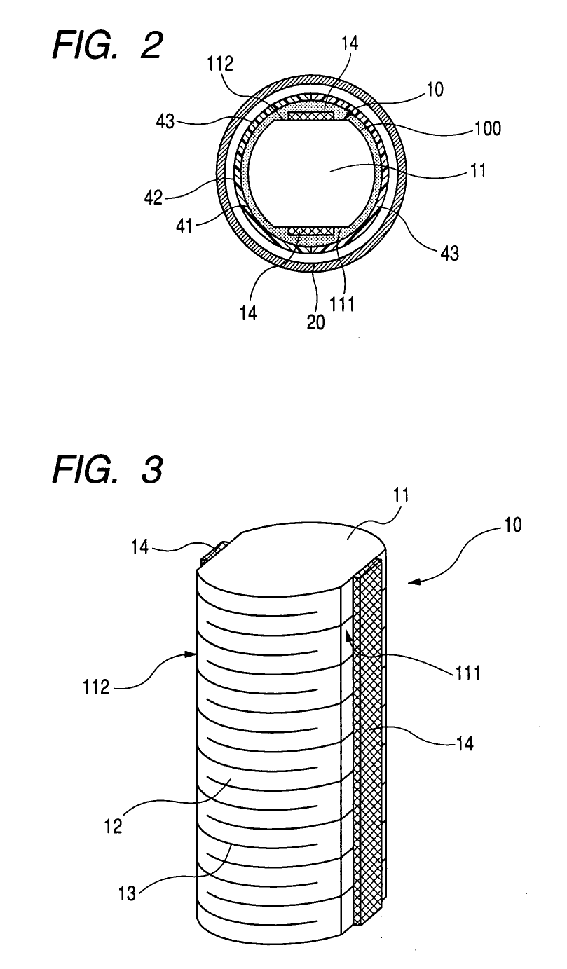

As shown in FIGS. 1 and 2, between the piezoelectric device 10 and the cylindrical case 20, a molding resin 41 having an electric insulation property is provided on an outer circumferential surface 100 of the piezoelectric device 10 and a sleeve 42 having an electric insulation property is provided on the molding resin 41. The sleeve 42 is formed by a plurality of circumferentially separated sleeve segments 43 that are. assembled together into a substantially cylindrical shape.

The stacked piezoelectric device 10, as shown in FIG. 3, has a ceramic stacked body 11 formed by piezoelectric layers 12 and internal electrode layers 13 stacked alternately. The ceramic stacked body 11 is generally barrel-shaped in transverse cross section and has a pair of electrode bonding surfaces 111 and 112 formed in diametrically opposed relation on an outer circumferential surface of the ceramic stacked body 11.

A side surface electrode 14 is disposed on each of the electrode bonding surfaces 111 and 113, the side surface electrode 14 being indicated by cross hatching for clarity. Each side surface electrode 14 is electrically connected to alternate layers of the internal electrode layers 13, and those of the internal electrode layers which are electrically connected to one side surface electrode 14 are in an electrically insulated condition with respect to the other side surface electrode 14. Thus, the ceramic stacked body 11 has a so-called partial electrode structure. Each side surface electrodes 14 has an end adapted for electric connection with a corresponding one of the external electrodes 31 that is arranged to extend through the housing 30.

In the illustrated embodiment, the piezoelectric layers 12 are formed by a piezoelectric ceramic composed of lead zirconium titrate (PZT). The internal electrode layers 13 are made of an alloy of silver and palladium (Ag/Pd alloy). The side surface electrodes 14 are each formed by an electrically conductive adhesive (not shown) of epoxy resin containing Ag filler, and a takeout electrode (not shown) of expanded metal screen embedded in the conductive adhesive.

Referring back to FIG. 1, a substantially column-shaped or cylindrical block member 18 of alumina is disposed on one end face (upper end face in FIG. 1) of the ceramic stacked body 11. The block member 18 is in abutment with an end face at an inserting portion 32 of the housing 30 to thereby control the position of the piezoelectric device 10 accommodated within the case 20. A transfer member 19 of alumina is disposed on the other end face (lower end face in FIG. 1) of the piezoelectric device 10 for transferring a driving force from the piezoelectric device 10 to a driving plate 22 of the case 20. The transfer member 19 is formed jointly by a joint portion 191 and a rod portion 192. The joint portion 191 is joined by bonding to the lower end face of the ceramic stacked body 11, and the rod portion 192 is arranged to undergo abutting engagement with the driving plate 22 while the piezoelectric actuator 1 is in use.

The case 20 has a bottomed cylindrical shape and includes a substantially cylindrical body portion 23 and a bottom portion formed by the driving plate 22. The body portion 23 and the driving plate 22 are joined together by laser welding. At an end of the body portion 23 located adjacent to the driving plate 22 there is provided a metal bellows of austenitic-ferritic stainless steel as the extendable and contractible portion 21. The extendable and contractible portion 21 is disposed around the rod portion 192 of the transfer member 19. The driving plate 22 has a reaction surface 221 for receiving the driving force from the piezoelectric device 10 via the transfer member 19, and an operating surface 222 for outputting the driving force from the piezoelectric device 10 to the outside of the piezoelectric actuator 1. The driving plate 22 is in abutment with the transfer member 19 at the reaction surface 221 thereof while the piezoelectric actuator 1 is in use.

As shown in FIG. 1, the housing 30 is a substantially cylindrical member (not designated) made of austenitic-ferritic stainless steel and has the pair of external electrodes 31 of Fe—Ni alloy arranged to project into and extend through the cylindrical housing 30 in the axial direction of the cylindrical housing 30. A space defined between the housing 30 and each of the external electrodes 31 is sealed by a hermetic seal of glass. The inserting portion 32 of the housing 30 is inserted in the body portion 23 of the cylindrical case 20 so as to close the open end 291 of the case 20. The open end 201 of the case 20 and the inserting portion 32 of the housing 30 are joined together by laser welding so that an internal space of the case 20 is in a hermetically sealed condition.

As shown in FIGS. 1 and 2, between the piezoelectric device 10 and the case 20, the molding resin 41 having an electric insulation property is provided on the outer circumferential surface of the piezoelectric device 10 and the sleeve 42 having an electric insulation property is provided on the molding resin 41. The sleeve 42 is formed by a plurality of sleeve segments 43 separated in the circumferential direction of the sleeve 42 and assembled together into a substantially cylindrical shape. In the illustrated embodiment, the sleeve 42 is composed of two semicylindrical sleeve halves or segments43 mated or assembled together in the circumferential direction of the sleeve 42.

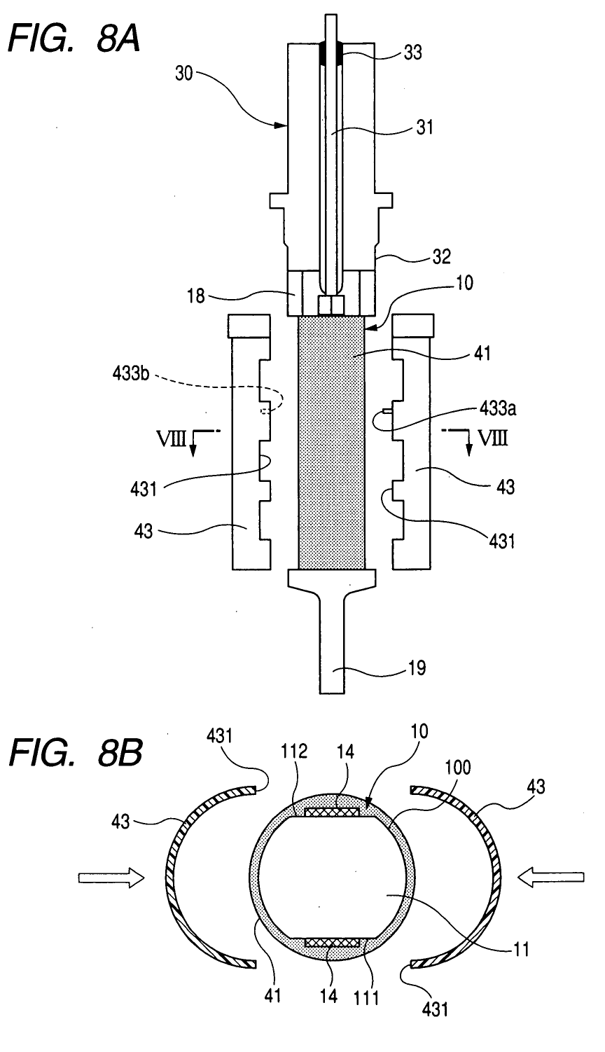

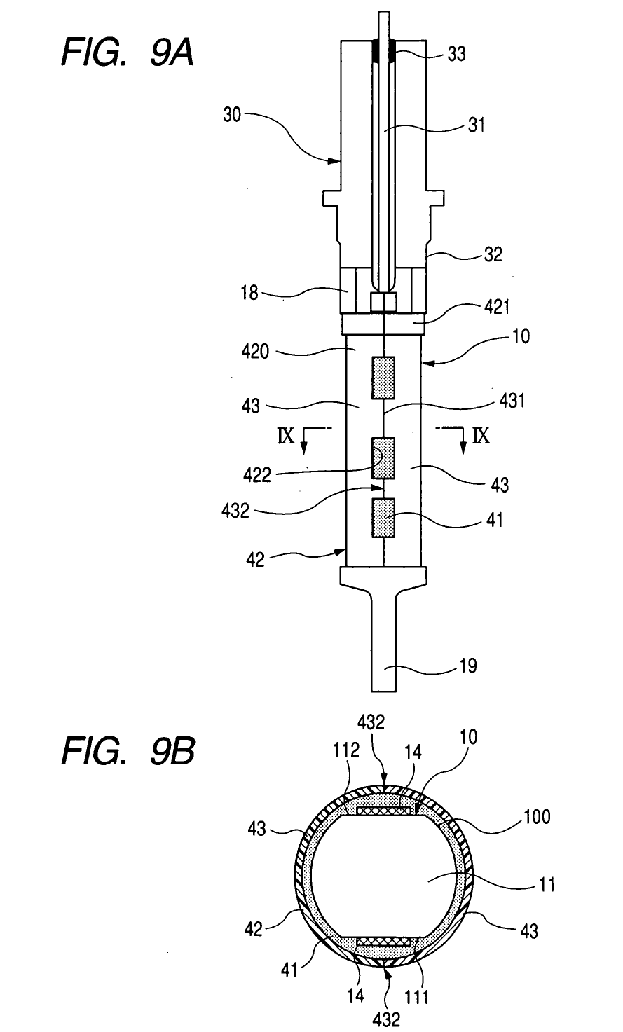

The sleeve 42 has a large-diameter portion 421 formed on an outer circumferential surface 420 thereof for the purpose of aligning the piezoelectric device 10 and the case 20. The large-diameter portion 643 is in contact with an inner circumferential surface 202 of the cylindrical case 20 so as to prevent the piezoelectric device 10 from displacing out of alignment with the cylindrical case. As shown in FIG. 8A, opposite end surfaces 431 of each sleeve segment 43, which face in a circumferential direction of the sleeve 42, have alternating ridges and grooves arranged in the axial direction of the sleeve 42. With the ridges and grooves thus formed on the end surfaces 431 of each sleeve segment 43, when the two sleeve segments 43 are mated together at their end surfaces 431, as shown in FIG. 9A, a plurality of communication holes 422 are formed at mating portions 432 of the sleeve segments 43. The molding resin 41 provided interiorly of the sleeve 42 is exposed to the view through the communicating holes 422. One sleeve segment 43 (right sleeve segment in FIG. 8A) has a projection 433a formed as a first engagement portion on the opposite end surfaces 431 thereof for positioning the two sleeve segments relative to each other. Similarly, the other sleeve segment 43 (left sleeve segment in FIG. 8A) has a recess 433b formed as a second engagement portion in the opposite end surfaces 431 thereof. The positioning engagement portion (projection) 433a of the right sleeve segment 43 and the positioning engagement portion (recess) 433b of the left sleeve segment 43 are engaged or fitted with each other to join the sleeve segments 43 in the circumferential direction thereof. The projection 433a and the recess 433a may be replaced with a rib formed on one of opposed mating surfaces of the sleeve segments 43 and extending in the axial direction of the sleeve segments 43 and a groove formed in the other of the mating surfaces of the sleeve segments 43 for receiving the rib.

In the illustrated embodiment, a silicone resin is used as the molding resin 41 and polyphenylene sulfide (PPS) is used as the material for the sleeve segments 43.

Next, a production method of the piezoelectric actuator 1 will be described. The piezoelectric actuator production method of the invention includes at least a resin application step, sleeve assembly step, resin curing step, piezoelectric device placement step, and housing and case joining step that are performed in the named order.

Firstly, in the resin application step, a molding resin having an electric insulation property is applied to an outer circumferential surface 100 of a piezoelectric device 10. Then, in the sleeve assembly step, a plurality of sleeve segments 43 are placed on the outer circumferential surface 100 of the piezoelectric device 10 in a circumferentially mated condition with the molding resin 41 interposed between the piezoelectric device 10 and the sleeve segments to thereby assemble the sleeve segments 43 into a substantially cylindrical sleeve 42. Thereafter, in the resin curing step, the molding resin 41, which has been applied to the outer circumferential surface 100 of the piezoelectric device 10, is cured. Then, in the piezoelectric device placement step, the piezoelectric device 10 is placed in a case 20. Finally in the housing and case joining step, a housing 30 is arranged so as to close or seal an open end 201 of the case 20 and thereafter the housing 30 and the case 20 are joined together.

The foregoing production method will be explained in further detail. At first, a process is performed to produce the piezoelectric device 10. In this process, a ceramic raw material powder consisting of lead zirconium titrate (PZT) is prepared as a piezoelectric material, and a solvent, binder, plasticizer, and dispersant are added to this ceramic powder to form a slurry. Then, using a doctor blade, the slurry is coated over a carrier film so as to form a green sheet (not shown) having a predetermined thickness. As a green sheet shaping method, extrusion molding and various other techniques can be used in place of the doctor blade.

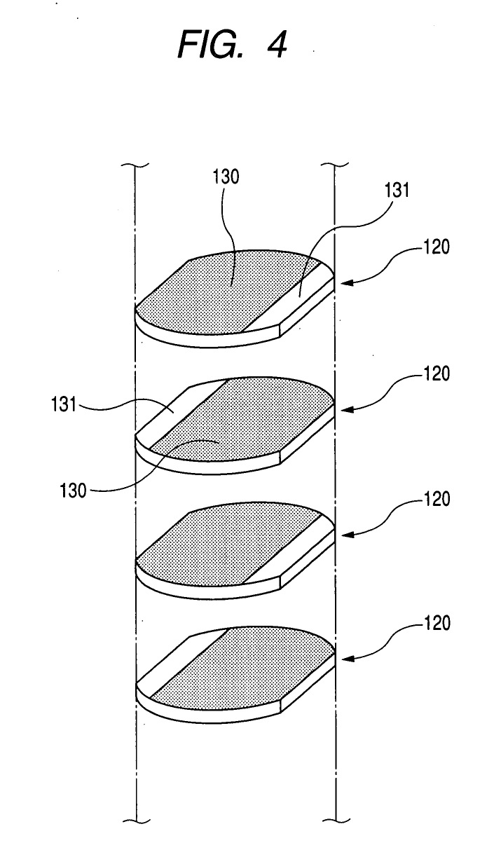

Next, an electrode material 130 (FIG. 4) is applied to that part of the green sheet, which form internal electrodes 13. The green sheet is then profile-cut or punched into sheet pieces 120 (FIG. 4) having a desired shape and configuration. The sheet pieces 120 have an electrode-free portion 13, which has not been coated with the electrode material 130. As the electrode material a paste of AG/Pd alloy is used.

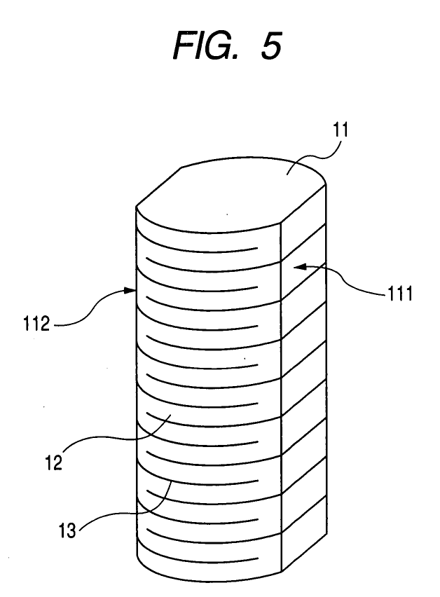

Then, as shown in FIG. 4, the sheet pieces 120 are stacked one above another to form an intermediate stacked body (not shown). In this instance, stacking is performed in such a fashion that the electrode-free portions 131 of the sheet pieces 120 are alternately positioned on the right and left in the drawing. After subjected to degreasing, the intermediate stacked body is baked at 900 to 1000° C. for 1 to 5 hours. As a result, a ceramic stacked body 11 having piezoelectric layers 12 and internal electrode layers 13 stacked alternately as shown in FIG. 5 is obtained.

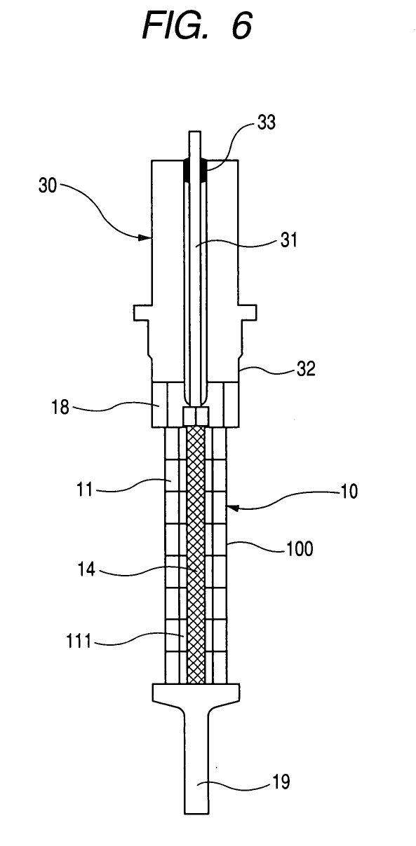

Next, an electrically conductive adhesive (not shown) is applied to electrode bonding surfaces 111 and 112 of the ceramic stacked body 11 and, thereafter, a pair of takeout electrodes (not shown) are placed on layers of the electrically conductive adhesive coated on the electrode bonding surfaces 111, 112, followed by heat-curing of the electrically conductive adhesive to thereby join the takeout electrodes to the ceramic stacked body 11. As a consequence of this joining, side surface electrodes 14 (one being shown in FIG. 6) are formed on the electrode bonding surfaces 111, 112 (FIG. 5) of the ceramic stacked body 11. A piezoelectric device, such as shown in FIG. 3, is thus produced.

Then a process is performed to place or assemble the piezoelectric device 10 into the housing 30. As shown in FIG. 6, a block member 18 is connected to one end face in the stacking direction of the ceramic stacked body 11 of the piezoelectric device 10, and a transfer member 19 is connected to the other end face in the stacking direction of the ceramic stacked body 11. Next, ends of the side surface electrodes 14 of the piezoelectric device 10 and the external electrodes 31 of the housing 30 are joined by spot welding. Then, the block member 18 and the inserting portion 32 of the housing 30 are held in abutment with each other and, while keeping this condition, the piezoelectric device 10 and the housing 30 are assembled together. A space defined between each of the external electrodes 31 and the housing 30 is sealed by a hermetic seal 33 made of glass.

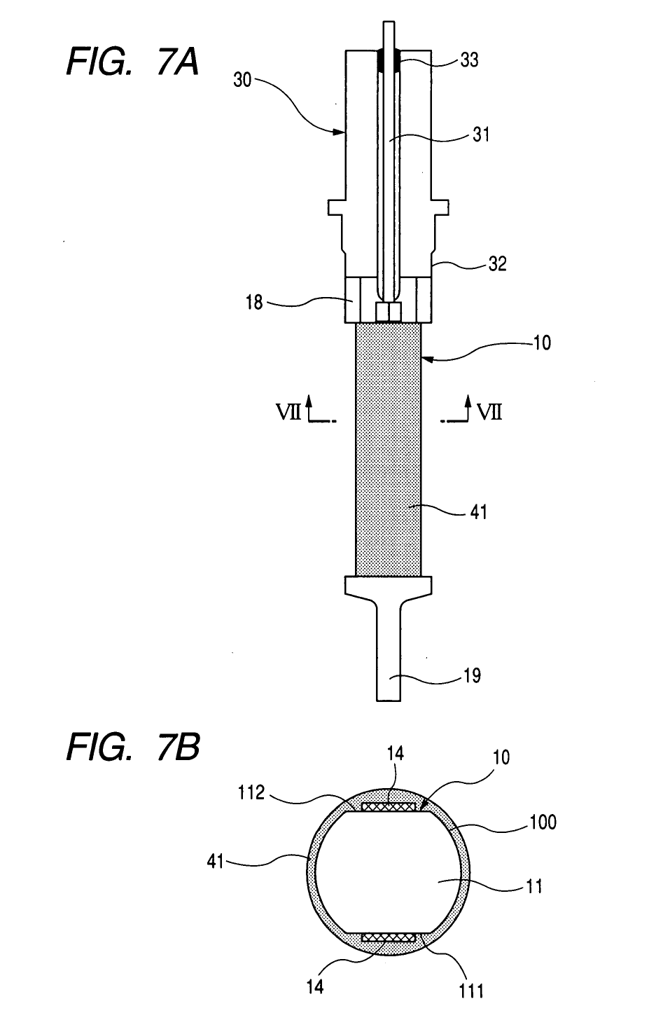

In the mold application step, the molding resin 41 is applied to the entire area of the outer circumferential surface 100 of the piezoelectric device 10 as shown in FIGS. 7A and 7B.

Then, in the sleeve assembly step, as shown in FIGS. 8A and 8B, two semicylindrical sleeve segments 43 of identical configuration are placed on the molding resin 41 applied to the outer circumferential surface 100 of the piezoelectric device 10 in such a manner that the sleeve segments 43 are mated together in the circumferential direction thereof In this instance, the positioning engagement portions (projections) 433a provided on opposite end surfaces 431 of one sleeve segment 43 and the positioning engagement portions (recesses) 433b formed in opposite end surfaces 431 of the other sleeve 43 are brought into interlocking engagement with each other. Placement of the sleeve segments 43 are performed while monitoring the application quantity and condition of the molding resin so as to ensure that the molding resin 41 provided between the piezoelectric device 10 and the sleeve segments 43 has a uniform film thickness.

A split sleeve 42 of substantially cylindrical configuration composed of two semicylindrical sleeve segments 43 is thus formed around the outer circumferential surface 100 of the piezoelectric device 10 with the molding resin 41 interposed between the sleeve 42 and the piezoelectric device 10, as shown in FIGS. 9A and 9B. The sleeve 42 has on its outer circumferential surface 420 a large-diameter portion 421, which is provided for alignment of the piezoelectric device 10 with the cylindrical case 20. The sleeve 42 further has communicating holes 422 formed at mating portions 432 of the sleeve segments 43 by and between opposite end surfaces 431 in the circumferential direction of the sleeve segments 43 including the alternating ridges and grooves. arranged in the axial direction of the sleeve 42.

Next, in the resin curing step, the molding resin 41 provided between the piezoelectric device 10 and the sleeve 42 is cured by heating the same. By thus curing the molding resin 41, the sleeve 42 is firmly secured to the outer circumferential surface 100 of the piezoelectric device 10 via the molding resin 41.

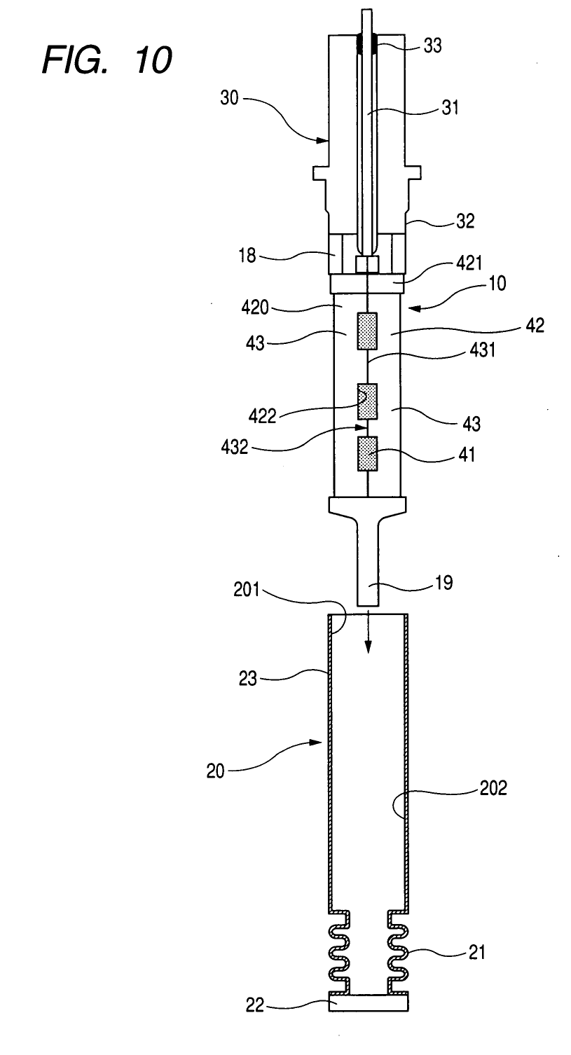

In the piezoelectric device placement step, as shown in FIG. 10, the piezoelectric device 10 is placed in the case 20 from the open end 201 of the case 20. In this instance, since the large-diameter portion 421 provided for alignment purposes on the outer circumferential surface 420 of the sleeve 42 comes into sliding contact with an inner circumferential surface 202 of the case 20, the piezoelectric device 10 is locked in position again movement in a radial direction relative to the case 20. Thus, the piezoelectric device 10 is held in alignment with the case 20.

Finally in the housing and case joining step, as shown in FIG. 1, the housing 30 is arranged so as to close or seal the open end 201 of the case 20. More particularly, the inserting portion 32 of the housing 30 is inserted in the open end 201 of the case 20, then the open end 201 of the case 20 and the inserting portion 32 of the housing 30 are joined by laser welding. In the illustrated embodiment, by irradiating all around the open end 201 of the case 20 with a laser beam emitted from the external side of the case 20, the open end 201 of the case 20 and the inserting portion 32 of the housing 30 are fusion-bonded so that the case 20 and the housing 30 are firmly joined together. The internal space of the case 20 is kept in a hermetically sealed condition. A piezoelectric actuator 1, such as shown in FIG. 1, is thus produced.

Next, various advantageous effects attained by the piezoelectric actuator 1 of the first embodiment of the invention will be described in detail. The piezoelectric actuator 1 is produced in accordance with the production method just described above. In the production method, the sleeve assembly step is carried out by placing the sleeve segments 43 on the outer circumferential surface 100 of the piezoelectric device 10 in a circumferentially mated condition with the molding resin 41 interposed between the piezoelectric device 10 and the sleeve segments to thereby assemble the sleeve segments together into a substantially cylindrical sleeve 42.

In the sleeve assembly step, instead of inserting the piezoelectric device into a cylindrical sleeve of one-piece unitary structure to thereby provide the sleeve on and around the outer circumferential surface of the piezoelectric device as done in the conventional piezoelectric actuator production method, a split sleeve 42 composed of a plurality of sleeve segments 43 separated in advance in a circumferential direction of the sleeve 42 is used and the sleeve segments 43 are placed on and around the outer circumference surface 100 of the piezoelectric device 10 and mated or assembled together in the circumferential direction to thereby form the sleeve 42 of a cylindrical shape. Positioning of the sleeve segments 43 in the circumferential direction is easy to achieve so that the sleeve 42 can be formed with increased accuracy.

Furthermore, in the sleeve assembly step, the sleeve 42 is formed by placing the sleeve segments 43 on and around the outer circumferential surface 100 of the piezoelectric device 10 while confirming or monitoring the application quantity and condition of the molding resin 41 interposed between the piezoelectric device 10 and the sleeve 42. It is therefore possible to prevent homogeneity degradation and squeeze-out of the molding resin 41, which would otherwise occur when the sleeve has a conventional one-piece unitary structure. Thus, the film thickness of the molding resin 41 can be controlled easily and the uniformity in thickness of the molding resin 41 can be maintained sufficiently.

Additionally, by virtue of the sleeve 42 which is accurately provided on the outer circumferential surface 100 of the piezoelectric device 10 with the molding resin 41 having a uniform film thickness disposed therebetween, it is possible to provide sufficient electric insulation between the piezoelectric device 10 and the case 20. As a result, the piezoelectric actuator 1 produced in accordance with the method of the present invention has very high quality, which is particularly excellent in terms of the durability and reliability.

Furthermore, according to the method of the present invention, the film thickness of the molding resin 41 can be easily controlled as previously described and, accordingly, application quantity of the molding resin 41 can be limited to a minimum necessary quantity. As a consequence, excess application of the molding resin 41 can be avoided and a separate work or operation for removing an excess amount of molding resin is no longer necessary. Thus, the productivity of the piezoelectric actuator 1 is improved.

In the resin application step, the molding resin 41 is applied to the outer circumferential surface 100 of the piezoelectric device 10, In this instance, the sleeve assembly step is carried out by placing the sleeve segments 43 on the outer peripheral surface 100 of the piezoelectric device 10 which is coated with the molding resin. This arrangement allows for placement of the sleeve segments 43 while performing visual confirmation or monitoring of the application quantity and condition of the molding resin 41.

In the sleeve assembly step, the sleeve segments 43 are mated or assembled together to form a cylindrical sleeve 42 with a large-diameter portion 421 formed on an outer circumferential surface 420 of the sleeve 42 for the purpose of alignment, and in the piezoelectric device placement step, the large-diameter portion 421 of the sleeve 42 is held in contact with an inner circumferential surface 202 of the case 20. With this arrangement, since the large-diameter portion 421 operates to keep constant spacing between the piezoelectric device 10 and the case 20 and fix the axis of the piezoelectric device 10 in position relative to the case 20. This will ensure that the piezoelectric device 10 is completely free from eccentricity relative to the case 20 and the vibration resistance of the piezoelectric actuator 1 increases further.

Furthermore, the sleeve assembly step is achieved such that positioning engagement portions 433a, 433b provided on opposite end surfaces 431 in the circumferential direction of the sleeve segments are engaged together to thereby assemble the sleeve segments 43 into the cylindrical sleeve. In this case, positioning of the sleeve segments 43 in the circumferential direction can be achieved more easily and the sleeve segments 43 can be joined with increased reliability. Regardless of its split structure composed of a plurality of sleeve segments 43, the sleeve 42 is highly accurate in construction and has a high mechanical strength.

In the sleeve assembly step, when the sleeve segments 43 are mated together, communicating holes 422 are formed at mating portions 432 of the sleeve segments 43 so that the molding resin 41 disposed inside the sleeve 42 is exposed to the view through the communicating holes 422. In this case, it is readily possible to perform a visual observation through the communicating holes 422 so as to confirm whether the molding resin 41 has been applied (or filled) uniformly and sufficiently between the piezoelectric device 10 and the sleeve 42. With this visual observation, the film thickness of the molding resin 41 can be controlled easily and accurately.

As thus far described, the piezoelectric actuator production method of the present invention is able to improve the productivity of the piezoelectric actuator 1. The piezoelectric actuator 1 produced in accordance with the production method of the invention has an excellent electric insulation property, leading to an improvement in the quality particularly in terms of the durability and reliability.

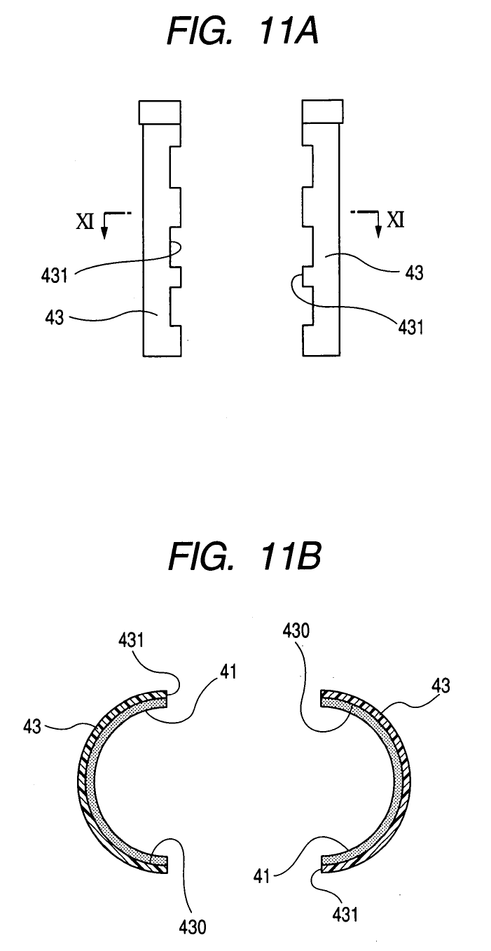

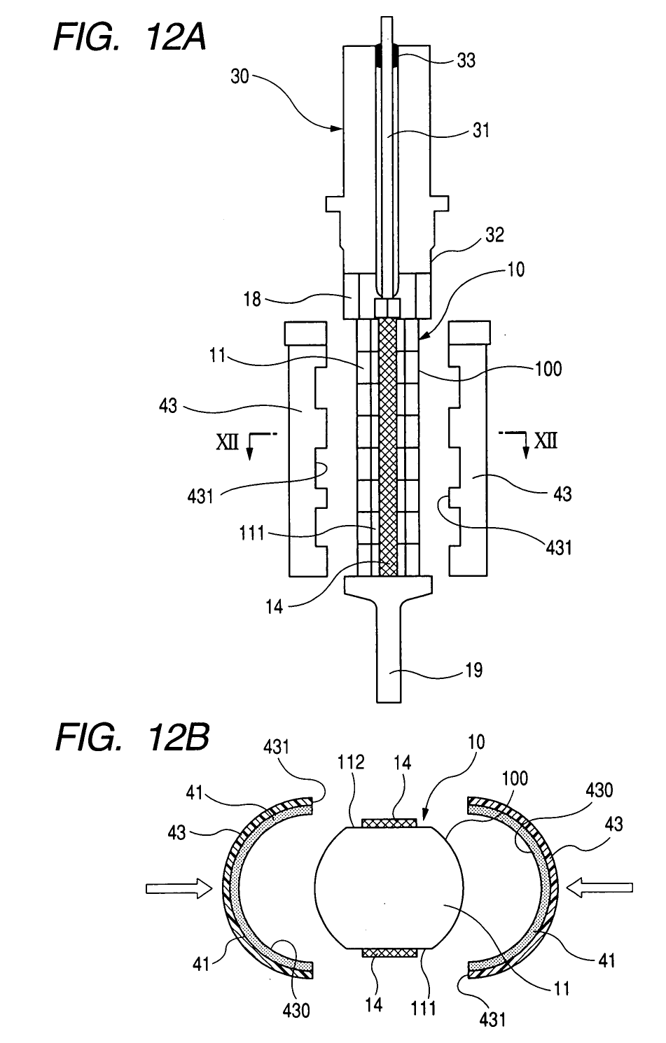

Next, a piezoelectric actuator production method according to a second embodiment of the invention will be described with reference to FIGS. 11A-11B and 12A-12B. The production method of this embodiment differs from the method of the first embodiment in terms of the resin application step and the sleeve assembly step.

In this embodiment, the resin application step is carried out by applying a molding resin 41 to inner circumferential surfaces 430 of two semicylindrical sleeve segments 43 of identical configuration, as shown in FIGS. 11A and 11B. Then, in the sleeve assembly step, as shown in FIGS. 12A and 12B, the sleeve segments 43 coated on its inner circumferential surfaces with the molding resin 41 are placed on and around the outer peripheral surface 100 of the piezoelectric device 10 so that a substantially cylindrical sleeve 42 composed of the two identical semicylindrical sleeve segments 43, such as shown in FIGS. 9A and 9B, is produced. Other processing steps are the same as those in the first embodiment described above with reference to FIGS. 1 to 10 and further description thereof can be omitted.

Likewise the first embodiment, the second embodiment allows for placement of the sleeve segments 43 while performing visual observation to confirm the application quantity and condition of the molding resin 41. Thus, the film thickness of the molding resin 41 can be maintained constantly, which will lead to production of a sleeve 42 with increased accuracy. As for the rest, the same advantageous effects as described above with respect to the first embodiment can be also attained in the second embodiment.

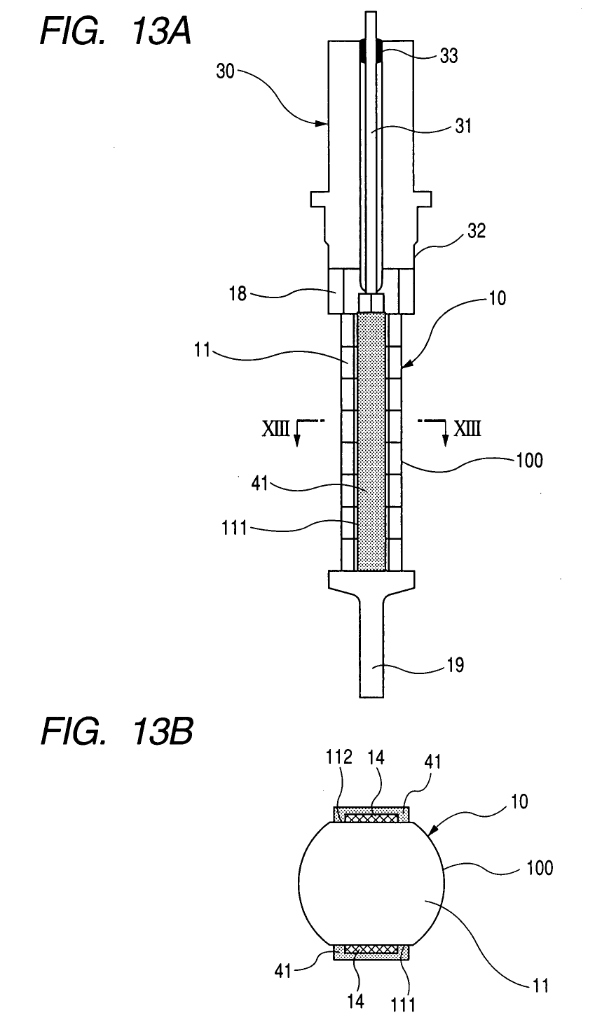

Description will be made to a piezoelectric actuator production method according to a third embodiment of the present invention. This embodiment represents the example where the resin application step and the sleeve assembly step of the first embodiment are modified as shown in FIGS. 13A-13B, 14A-14B and 15A-15B.

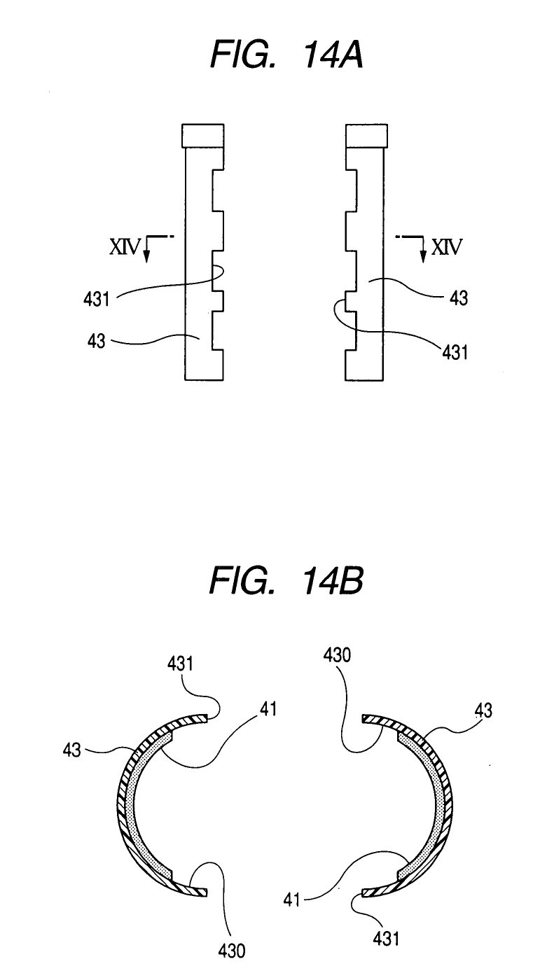

In this embodiment, the resin application step is carried out by applying a molding resin 41to the side surface electrodes 14 formed on the outer circumferential surface 100 of the piezoelectric device 10, as shown in FIGS. 13A and 13B. As shown in FIGS. 14A and 14B, the molding resin 41 is also applied by stamp bonding to that part of the inner circumferential surfaces 430 of the semicylindrical sleeve segments 43 which corresponds in position to, and hence will be finally placed on, that part of the outer circumferential surface 100 of the piezoelectric device 10 which is free from the molding resin 41.

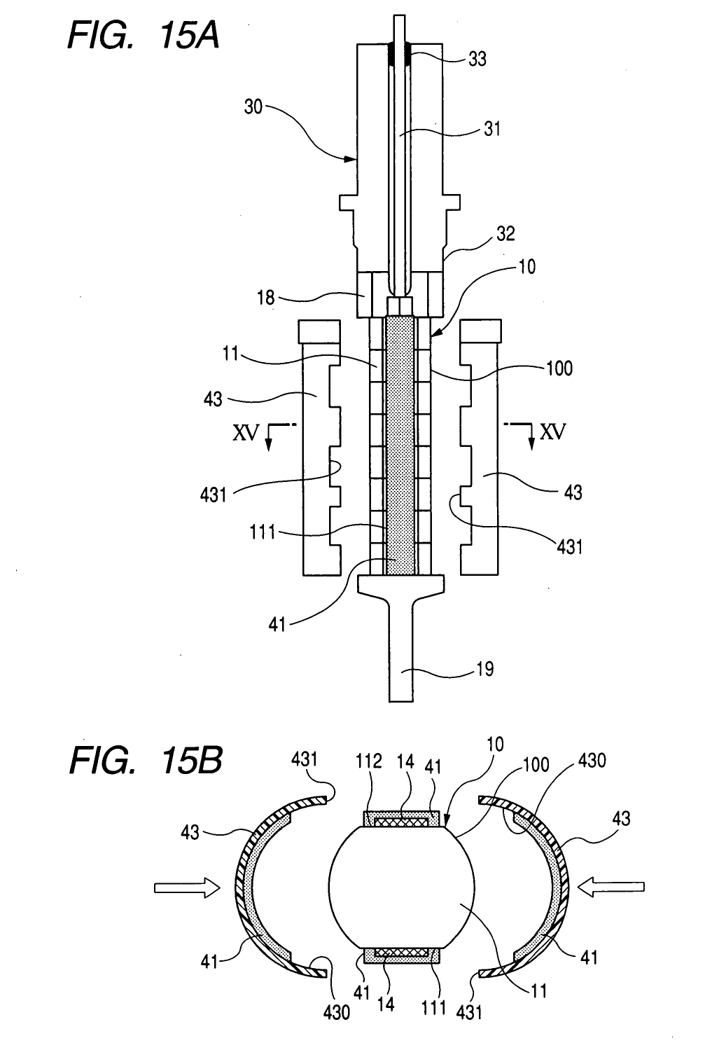

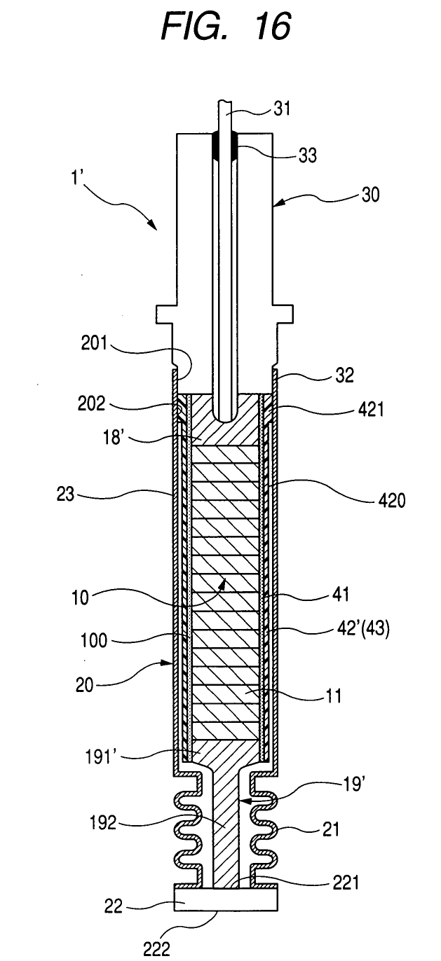

Next in the sleeve assembly step, as shown in FIGS. 15A and 15B, the sleeve segments 43 are placed on the outer circumferential surfaces 100 of the piezoelectric device 10 in such a manner that the molding resin 41 applied to the inner circumferential surfaces 430 of the sleeve segments 43 is in match with the molding resin-free part of the outer peripheral surface 100 of the piezoelectric device 10. A substantially cylindrical sleeve 42 having a split structure composed of the sleeve segments 43 can thus be formed. Other processing steps are the same as those in the first embodiment described above with reference to FIGS. 1 to 10 and further description thereof can be omitted.

Likewise the first embodiment, the second embodiment also allows for placement of the sleeve segments 43 to form the sleeve 42 while performing visual observation to confirm the application quantity and condition of the molding resin 41. Thus, the film thickness of the molding resin 41 can be made uniform, which will leads to formation of a sleeve with increased accuracy. Furthermore, by using the stamp bonding, it is readily possible to apply a necessary amount of molding resin only to a desired part of the sleeve segments. Accordingly, excess application of the molding resin can be avoided. As for the rest, the same advantageous effects as described above with respect to the first embodiment can be also attained in the second embodiment.

FIG. 16 shows a piezoelectric actuator 1′ according to a fourth embodiment of the present invention, which is differentiated from the piezoelectric actuator 1 of the first embodiment by structural components accommodated within the case 20.

In the piezoelectric actuator ′ shown in FIG. 16, a block member 18′ disposed on one end face in the stacking direction of a ceramic stacked body 11 has a same diameter as the ceramic stacked body 11. Similarly, a transfer member 19′ disposed on the other end face in the stacking direction of the ceramic stacked body 11 includes a joint portion 19′ having the same diameter as the ceramic stacked body 11. A molding resin 41 is applied to cover outer circumferential surfaces of the block member 18′, ceramic stacked body 11, and joint portion 19′ of the transfer member 19. A sleeve 42′ is fitted over the molding resin 41. The sleeve 42′ has a large-diameter portion 421, which is in contact with an inner circumferential surface 202 of the case 20 in a radial direction of the sleeve 42 and also in abutment with an inserting portion 32 of a housing 30 in an axial direction of the sleeve 42. The sleeve assembly step may be carried out in the same manner as done in any of the first to third embodiments of the present invention described previously. Other structural parts or components are the same as those in the first embodiment and the same advantageous effects as described above with respect to the first embodiment can be also attained in the fourth embodiment.

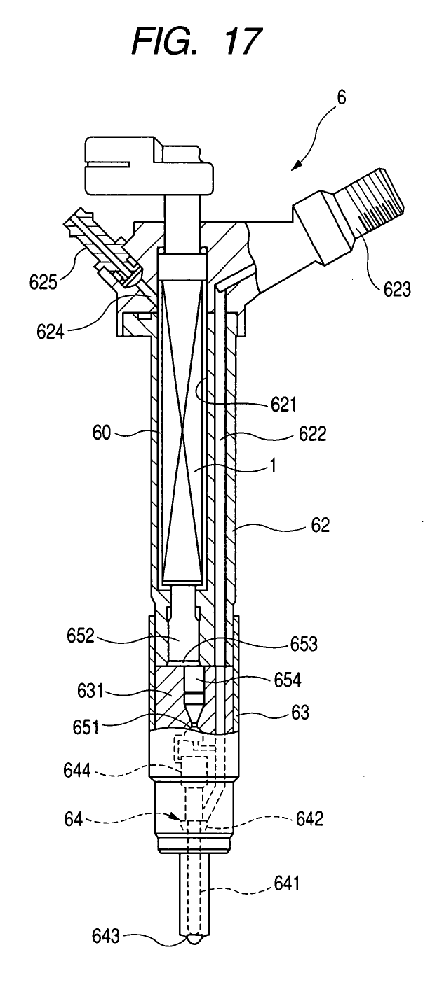

FIG. 17 shows a fifth embodiment of the present invention, which represents an example in which the piezoelectric actuator 1 of the first embodiment is incorporated in an injector 6. As shown in FIG. 17, the injector 6 is used in a common rail injection system for diesel engines. The injector 6 has an upper housing 62 in which the piezoelectric actuator 1 is disposed as a drive unit, and a lower housing 63 secured to a lower end of the upper housing 62 and having formed therein an injection nozzle portion 64.

The upper housing 62 is a substantially hollow cylinder and has an axial hole 621 formed in eccentric relation to a central axis of the cylindrical upper housing 62. The piezoelectric actuator 1 is inserted in the axial hole 621 and fixed in position within the axial hole 621. A high-pressure fuel passage 622 extends in the upper housing 62 in parallel spaced relation to the axial hole 622 on one lateral side of the axial hole 62. The high-pressure fuel passage 622 is connected to an external common rail (not shown) via a fuel supply tube 623 protruding obliquely upward from an upper part of the upper housing 62.

A fuel return tube 625 protrudes obliquely upward from the upper part of the upper housing 62 and communicates with a drain passage 624, and a fuel flowing out from the fuel return tube 62 is retuned to a fuel tank (not shown). The drain passage 624 is connected to a three-way valve 651 via a clearance 60 defined between the axial hole 621 and the drive unit 1 (piezoelectric actuator) and another passage (not shown) extending downwardly from the clearance 60 through the upper and lower housings 62 and 63.

The injection nozzle portion 64 includes a nozzle needle 641 slidably movable up and down inside a piston body 631, and an injection hole 643 selectively opened and closed by the nozzle needle 641 for injecting high-pressure fuel supplied from a fuel reservoir 642 into a cylinder of an engine. The fuel reservoir 642 is disposed at and around an intermediate portion of the nozzle needle 641, and the lower end of the high-pressure fuel passage 622 opens here. The nozzle needle 641 receives the fuel pressure from the fuel reservoir 642 in a valve-opening direction and the fuel pressure in a back pressure chamber 644 so disposed as to face the upper end face in a valve-closing direction. The nozzle needle 641 is lifted when the pressure of the back pressure chamber 644 drops to open the injection hole 643 and to release the fuel.

The three-way valve 651 increases or decreases the pressure of the back pressure chamber 644. The three-way valve 651 is selectively communicated with the back pressure chamber 644 and the high-pressure fuel passage 622 or with the drain passage 624. In the illustrated embodiment, the three-way valve 651 has a ball-like valve body for opening and closing a port communicating with the high-pressure fuel passage 622 or the drain passage 624. The drive unit 1 (piezoelectric actuator) drives the valve body through a large-diameter piston 652, an oil pressure chamber 653 and a small-diameter piston 654 disposed below the valve body.

In the embodiment shown in FIG. 17, the piezoelectric actuator 1 of the first embodiment is used as a drive unit of the injector 6. Thanks to its superiority in quality including excellent durability and reliability, the piezoelectric actuator 1 is able to improve the overall performance of the injector 6.

While the present invention has been described by reference to specific embodiments chosen for purposes of illustration, it should be apparent that numerous modifications could be made thereto by those skilled in the art without departing from the basic concept and scope of the invention.

What is claimed is:

1. A piezoelectric actuator comprising:
a case having a bottomed cylindrical shape including an extendable and contractible portion formed at least at a part of the cylindrical case in an axial direction thereof;
a stacked piezoelectric device received in the cylindrical case;
a housing provided with a pair of external electrodes for power supply and connected to an open end of the cylindrical case;
a molding resin having an electric insulation property and provided on an outer circumferential surface of the piezoelectric device between the piezoelectric device and the cylindrical case; and
a sleeve having an electric insulation property and provided on the molding resin, the sleeve being formed by a plurality of circumferentially separated sleeve segments assembled together into a substantially cylindrical shape.

2. A piezoelectric actuator according to claim 1, wherein the sleeve has a large-diameter portion formed on an outer circumferential surface thereof for the purpose of alignment, the large-diameter portion being in contact with an inner circumferential surface of the cylindrical case.

3. A piezoelectric actuator according to claim 1, wherein the sleeve has a communicating hole formed at mating portions of each adjacent two of the plurality of sleeve segments, and the molding resin disposed inside the sleeve is exposed to the view through the communicating hole.

4. A piezoelectric actuator according to claim 1, wherein each of the sleeve segments has an engagement portion disposed on opposite end surfaces at respective mating portions relative to the adjacent sleeve segment, the engagement portion of each sleeve segment and the engagement portion of the adjacent sleeve segment being engaged together to join the two sleeve segments in the circumferential direction to thereby assemble the sleeve.

5. A piezoelectric actuator according to claim 1, wherein the sleeve segments are formed from polyphenylene sulfide, polyethylene terephthalate, or nylon 66.

6. A piezoelectric actuator according to claim 1, wherein the molding resin is a silicone resin, epoxy resin, polyimide resin, or polyurethane resin.

7. A piezoelectric actuator according to claim 1, wherein the piezoelectric actuator is incorporated in a fuel injector of an internal combustion engine.

8. A method of producing a piezoelectric actuator comprised of a case having a bottomed cylindrical shape including an extendable and contractible portion formed at least at a part of the cylindrical case in an axial direction thereof, a stacked piezoelectric device received in the cylindrical case, and a housing provided with a pair of external electrodes for power supply and connected to an open end of the cylindrical case, the method comprising the steps of:
applying a molding resin having an electric insulation property to at least one of an outer circumferential surface of the piezoelectric device and inner circumferential surfaces of a plurality of circumferentially separated sleeve segments having an electric insulation property;
placing the sleeve segments on the outer circumferential surface of the piezoelectric device in a circumferentially mated condition with the molding resin interposed between the piezoelectric device and the sleeve segments to thereby assemble the sleeve segments together into a substantially cylindrical sleeve;
curing the molding resin;
placing the piezoelectric device into the cylindrical case; and
placing the housing in such a manner as to close an open end of the cylindrical case and joining the housing and the case together.

9. A method according to claim 8, wherein the applying a molding resin is carried out by applying the molding resin to the outer circumferential surface of the piezoelectric device, and the placing the sleeve segments is carried out by placing the sleeve segments on the outer peripheral surface of the piezoelectric device to which the molding resin has been applied.

10. A method according to claim 8, wherein the applying a molding resin is carried out by applying the molding resin to the respective inner circumferential surfaces of the sleeve segments, and the placing the sleeve segments is carried out by placing the sleeve segments on the outer peripheral surface of the piezoelectric device with the molding resin being applied to the inner circumferential surfaces of the sleeve segments.

11. A method according to claim 8, wherein the applying a molding resin is carried out by applying the molding resin to side surface electrodes connected to the respective external electrodes and provided on a pair of electrode bonding surfaces formed on the outer circumferential surface of the piezoelectric device, and also applying the molding resin by stamp-bonding to that part of the inner circumferential surfaces of the sleeve segments which will be finally placed on that part of the outer circumferential surface of the piezoelectric device which is free from the molding resin, and the placing the sleeve segments is carried out by placing the sleeve segments on the outer circumferential surfaces of the piezoelectric device in such a manner that the molding resin applied to the sleeve segments is in match with the molding resin-free part of the outer peripheral surface of the piezoelectric device.

12. A method according to claim 8, wherein the placing the sleeve segments further comprises providing a large diameter portion formed on an outer circumferential surface of the sleeve for the purpose of alignment.

13. A method according to claim 12, wherein the piezoelectric device is placed in the cylindrical case such that the large-diameter portion of the sleeve is in contact with an inner circumferential surface of the case.

14. A method according to claim 8, wherein the placing the sleeve segments is achieved such that positioning engagement portions provided on end surfaces of respective mating portions of two adjacent ones of the sleeve segments are engaged together to assemble the sleeve segments into the cylindrical sleeve.

15. A method according to claim 8, wherein the placing the sleeve segments is achieved such that a communicating hole is formed at mating portions of each adjacent two of the sleeve segments when the sleeve segments are assembled together into the cylindrical sleeve, and the molding resin disposed inside the sleeve is exposed to the view through the communicating hole.

16. A piezoelectric actuator according to claim 8, wherein the sleeve segments are formed from polyphenylene sulfide, polyethylene terephthalate, or nylon 66.

17. A piezoelectric actuator according to claim 8, wherein the molding resin is a silicone resin, epoxy resin, polyimide resin, or polyurethane resin.
